(19) United States
(12) Patent Application Publication
(10) Pub. No.: US 2025/0292990 A1
(43) Pub. Date: Sep. 18, 2025

(54) GAS MIXTURES FOR ION IMPLANTATION

(71) Applicant: ENTEGRIS, INC., Billerica, MA (US)

(72) Inventors: Ying Tang, Brookfield, CT (US); Joseph R. Despres, Middletown, CT (US); Paolo Moreschini, Newtown, CT (US); Edward E. Jones, Woodbury, CT (US); Joseph D. Sweeney, New Milford, CT (US)

(21) Appl. No.: 19/078,207

(22) Filed: Mar. 12, 2025

Related U.S. Application Data
(60) Provisional application No. 63/564,295, filed on Mar. 12, 2024.

(51) Int. Cl. H01J 37/16; H01J 37/317

(52) U.S. Cl. CPC H01J 37/16; H01J 37/3171; H01J 2237/006

(57) ABSTRACT

An assembly for ion implantation is provided herein. An assembly comprises at least one vessel configured to be fluidly coupled to an arc chamber of an ion implantation device. The at least one vessel comprises a gas component comprising BF₃ and B₂F₄. When the gas component is supplied from the at least one vessel to the arc chamber for implantation into a substrate, a beam current of boron ions generated from the gas component is greater than a beam current of boron ions generated from a control gas component. Related systems, including ion implantation systems, and related methods are provided herein.

### CROSS-REFERENCE TO RELATED APPLICATIONS

This application claims the benefit under 35 USC 119 of U.S. Provisional Patent Application No. 63/564,295, filed Mar. 12, 2024, the disclosure of which is hereby incorporated herein by reference in its entirety.

### FIELD

The present disclosure relates to gas mixtures for ion implantation, and related systems and related methods, among other things.

### BACKGROUND

Ion implantation involves implantation of a chemical species into a substrate, such as a microelectronic device wafer, by impingement of energetic ions onto the substrate. To generate the ionic implantation species, a gas is ionized to generate an ion beam.

### SUMMARY

Some embodiments relate to an assembly for ion implantation. In some embodiments, the assembly comprises at least one vessel configured to be fluidly coupled to an arc chamber of an ion implantation device. In some embodiments, the at least one vessel comprises a gas component. In some embodiments, the gas component comprises BF₃ and B₂F₄. In some embodiments, when the gas component is supplied from the at least one vessel to the arc chamber for implantation into a substrate, a beam current of boron ions generated from the gas component is greater than a beam current of boron ions generated from a control gas component.

Some embodiments relate to a system for ion implantation. In some embodiments, the system comprises an assembly. In some embodiments, the assembly comprises at least one vessel fluidly coupled to an arc chamber of an ion implantation device. In some embodiments, the at least one vessel comprises a gas component. In some embodiments, the gas component comprises BF₃ and B₂F₄. In some embodiments, when the gas component is supplied from the at least one vessel to the arc chamber for implantation into a substrate, a beam current of boron ions generated from the gas component is greater than a beam current of boron ions generated from a control gas component.

Some embodiments relate to a method for ion implantation. In some embodiments, the method comprises flowing a gas component from at least one vessel into an arc chamber of an ion implantation device. In some embodiments, the gas component comprises BF₃ and B₂F₄. In some embodiments, the method comprises producing boron ions, from the gas component, in the arc chamber of the ion implantation device. In some embodiments, the method comprises flowing the boron ions in a beam from the arc chamber to a target chamber for implantation into a substrate.

### DRAWINGS

Some embodiments of the disclosure are herein described, by way of example only, with reference to the accompanying drawings. With specific reference now to the drawings in detail, it is stressed that the embodiments shown are by way of example and for purposes of illustrative discussion of embodiments of the disclosure. In this regard, the description taken with the drawings makes apparent to those skilled in the art how embodiments of the disclosure may be practiced.

FIG. 1 depicts a schematic representation of an ion implantation system, according to some embodiments.

FIG. 2 is a flowchart of a method for ion implantation, according to some embodiments.

FIG. 3 is a graphical view of B⁺ beam current for varying total gas flow (sccm) for Control A and Sample A, according to some embodiments.

FIG. 4 is a graphical view of a beam spectrum for Control A and Sample A, according to some embodiments.

FIG. 5 is a graphical view of B⁺ beam current for varying total gas flow (sccm) for Control B and Sample B, according to some embodiments.

FIG. 6 is a graphical view of BF₂⁺ beam current for varying total gas flow (sccm) for Control C and Sample C, according to some embodiments.

FIG. 7 is a graphical view of a beam spectrum for Control C and Sample C, according to some embodiments.

FIG. 8 is a graphical view of BF₂⁺ beam current for varying total gas flow (sccm) for Control D and Sample D, according to some embodiments.

FIG. 9 is a graphical view of a beam spectrum for Control D and Sample D, according to some embodiments.

FIG. 10 is a graphical view of B⁺ beam current for gas mixtures with varying B₂F₄ concentrations, according to some embodiments.

### DETAILED DESCRIPTION

Some embodiments relate to gas mixtures for ion implantation. As disclosed herein, the gas mixtures for ion implantation exhibit an improvement in performance when used for ion implantation. For example, the gas mixtures disclosed herein, when used for ion implantation, unexpectedly extend source life by markedly reducing W⁺ peaks, among others. The gas mixtures disclosed herein, when used for ion implantation, unexpectedly increase B⁺ beam current. The gas mixtures disclosed herein, when used for ion implantation, unexpectedly increase BF₂⁺ beam current. The other benefits and improvements of the gas mixtures disclosed herein, along with the benefits and improvements of related systems, related methods, related devices, and related assemblies, among others, are apparent upon a review of this disclosure.

Some embodiments relate to an assembly. For example, in some embodiments, the assembly is a gas supply assembly. The assembly may comprise at least one vessel configured for containing a gas component. The at least one vessel may comprise a single vessel, or a plurality of vessels, such as, for example and without limitation, two vessels to one-hundred vessels, or any number of vessels between two vessels and one-hundred vessels. The at least one vessel may be configured for storing and supplying a gas component to an ion implantation device, such as, an arc chamber of an ion implantation device. In some embodiments, for example, the at least one vessel is configured to be fluidly coupled to an arc chamber of an ion implantation device.

In some embodiments, the gas component comprises boron. In some embodiments, the gas component comprises an isotopically-enriched boron.

As used herein, the term “isotopically-enriched” refers to a molecule in which an isotope is present above a reference amount. In some embodiments, the reference amount is a natural abundance level. For example, in some embodiments, a molecule comprising an isotopically-enriched boron refers to a molecule in which a boron isotope is present above natural abundance levels. In some embodiments, the reference amount is an initial amount of a boron isotope, and the molecule is modified to increase the amount of the boron isotope above the initial amount. The percentage increase can range from 1% to 100%, or any range or subrange between 1% and 100%, or in some instances greater than 100%. It will be appreciated an isotopically-enriched boron may comprise any isotope of boron, including, for example and without limitation, at least one of ⁶B, ⁷B, ⁸B, ⁹B, ¹⁰B, ¹¹B, ¹²B, ¹³B, ¹⁴B, ¹⁵B, ¹⁶B, ¹⁷B, ¹⁸B, ¹⁹B, ²⁰B, ²¹B, or any combination thereof.

In some embodiments, the at least one vessel comprises BF₃. In some embodiments, the BF₃ comprises isotopically-enriched boron.

In some embodiments, the at least one vessel comprises 1% to 99% by volume of the BF₃ based on a total volume of the gas component, or any range or subrange between 1% and 99%. In some embodiments, for example, the at least one vessel comprises 1% to 90%, 1% to 80%, 1% to 70%, 1% to 60%, 1% to 50%, 1% to 40%, 1% to 30%, 1% to 20%, 1% to 10%, 10% to 99%, 20% to 99%, 30% to 99%, 40% to 99%, 50% to 99%, 60% to 99%, 70% to 99%, 80% to 99%, or 90% to 99% by volume of the BF₃ based on the total volume of the gas component.

In some embodiments, the at least one vessel comprises B₂F₄. In some embodiments, the B₂F₄ comprises isotopically-enriched boron.

In some embodiments, the at least one vessel comprises 1% to 99% by volume of the B₂F₄ based on the total volume of the gas component, or any range or subrange between 1% and 99%. In some embodiments, for example, the at least one vessel comprises 1% to 90%, 1% to 80%, 1% to 70%, 1% to 60%, 1% to 50%, 1% to 40%, 1% to 30%, 1% to 20%, 1% to 10%, 10% to 99%, 20% to 99%, 30% to 99%, 40% to 99%, 50% to 99%, 60% to 99%, 70% to 99%, 80% to 99%, or 90% to 99% by volume of the B₂F₄ based on the total volume of the gas component.

In some embodiments, the at least one vessel comprises 2% to 50% by volume of the B₂F₄ based on the total volume of the gas component, or any range or subrange between 2% and 50%. For example, in some embodiments, the at least one vessel comprises 2% to 45%, 2% to 40%, 2% to 35%, 2% to 30%, 2% to 25%, 2% to 20%, 2% to 15%, 2% to 10%, 2% to 5%, 5% to 50%, 10% to 50%, 15% to 50%, 20% to 50%, 25% to 50%, 30% to 50%, 35% to 50%, 40% to 50%, or 45% to 50% by volume of the B₂F₄ based on the total volume of the gas component.

In some embodiments, the at least one vessel comprises 50% to 98% by volume of the BF₃ based on the total volume of the gas component, or any range or subrange between 50% and 98%. In some embodiments, the at least one vessel comprises 50% to 98%, 50% to 95%, 50% to 90%, 50% to 85%, 50% to 80%, 50% to 75%, 50% to 70%, 50% to 65%, 50% to 60%, 50% to 55%, 55% to 98%, 60% to 98%, 65% to 98%, 70% to 98%, 75% to 98%, 80% to 98%, 85% to 98%, 90% to 98%, or 95% to 98% by volume of the BF₃ based on the total volume of the gas component.

In some embodiments, the at least one vessel comprises 5% to 20% by volume of the B₂F₄ based on the total volume of the gas component, or any range or subrange between 5% and 20%. In some embodiments, the at least one vessel comprises 5% to 18%, 5% to 16%, 5% to 15%, 5% to 14%, 5% to 12%, 5% to 10%, 5% to 8%, 5% to 6%, 6% to 20%, 8% to 20%, 10% to 20%, 12% to 20%, 14% to 20%, 15% to 20%, 16% to 20%, or 18% to 20% by volume of the B₂F₄ based on the total volume of the gas component.

In some embodiments, the at least one vessel comprises 80% to 95% by volume of the BF₃ based on the total volume of the gas component, or any range or subrange between 80% and 95%. In some embodiments, the at least one vessel comprises 80% to 94%, 80% to 92%, 80% to 90%, 80% to 88%, 80% to 86%, 80% to 85%, 80% to 84%, 80% to 82%, 82% to 95%, 84% to 95%, 85% to 95%, 86% to 95%, 88% to 95%, 90% to 95%, 92% to 95%, or 94% to 95% by volume of the BF₃ based on the total volume of the gas component.

In some embodiments, the at least one vessel further comprises a second gas component. In some embodiments, the second gas component comprises at least one of a boron-containing gas, a hydrogen gas, a hydride gas, an inert gas, an ionizable gas, a diluent gas, a carrier gas, a co-gas, or any combination thereof. In some embodiments, the hydrogen gas comprises H₂. In some embodiments, the hydride gas comprises a compound of the formula AₓH_{y}, where A is an element other than hydrogen, x is 1 to 8, and y is 1 to 8. In some embodiments, the hydride gas comprises, for example, at least one of PH₃, AsH₃, B₂H₆, SiH₄, GeH₄, NH₃, or any combination thereof. In some embodiments, the inert gas comprises at least one of a nitrogen gas, a hydrogen gas, a neon gas, an argon gas, a krypton gas, a xenon gas, or any combination thereof. In some embodiments, the inert gas comprises at least one of an N₂ gas, a H₂ gas, a Ne gas, an Ar gas, a Kr gas, a Xe gas, or any combination thereof.

In some embodiments, the at least one vessel comprises 1% to 99% by volume of the gas component based on a total volume of the gas component and the second gas component, or any range or subrange between 1% and 99%. In some embodiments, for example, the at least one vessel comprises 1% to 90%, 1% to 80%, 1% to 70%, 1% to 60%, 1% to 50%, 1% to 40%, 1% to 30%, 1% to 20%, 1% to 10%, 10% to 99%, 20% to 99%, 30% to 99%, 40% to 99%, 50% to 99%, 60% to 99%, 70% to 99%, 80% to 99%, or 90% to 99% by volume of the gas component based on the total volume of the gas component and the second gas component.

In some embodiments, the at least one vessel comprises 1% to 99% by volume of the second gas component based on the total volume of the gas component and the second gas component. In some embodiments, for example, the at least one vessel comprises 1% to 90%, 1% to 80%, 1% to 70%, 1% to 60%, 1% to 50%, 1% to 40%, 1% to 30%, 1% to 20%, 1% to 10%, 10% to 99%, 20% to 99%, 30% to 99%, 40% to 99%, 50% to 99%, 60% to 99%, 70% to 99%, 80% to 99%, or 90% to 99% by volume of the second gas component based on the total volume of the gas component and the second gas component.

In some embodiments, the at least one vessel comprises at least one of the BF₃, the B₂F₄, the second gas component, or any combination thereof. In some embodiments, the at least one vessel comprises a single vessel. In some embodiments, the single vessel comprises at least one of the BF₃, the B₂F₄, the second gas component, or any combination thereof. In some embodiments, the at least one vessel comprises a first vessel and a second vessel. In some embodiments, the first vessel comprises at least one of the BF₃, the second gas component, or any combination thereof. In some embodiments, the second vessel comprises at least one of the B₂F₄, the second gas component, or any combination thereof. In some embodiments, the at least one vessel does not comprise at least one of the second gas components. In some embodiments, the first vessel does not comprise at least one of the second gas components. In some embodiments, the second vessel does not comprise at least one of the second gas components.

As used herein, the term “boron ions” refers to a substance comprising at least one boron ion. For example, in some embodiments, the boron ions comprise at least one of B⁺, BF₂⁺, or any combination thereof.

In some embodiments, when the gas component is supplied from the at least one vessel to the arc chamber for implantation into a substrate, a beam current of boron ions generated from the gas component is greater than a beam current of boron ions generated from a control gas component. In some embodiments, when the gas component is supplied from the at least one vessel to the arc chamber for implantation into a substrate, a beam current of boron ions generated from the gas component is at least 1% greater, 5% greater, 10% greater, 15% greater, 20% greater, 25% greater, 30% greater, 35% greater, 40% greater, 45% greater, 50% greater, 55% greater, 60% greater, 65% greater, 70% greater, 75% greater, 80% greater, 85% greater, 90% greater, or 95% greater than a beam current of boron ions generated from a control gas component. In some embodiments, when the gas component is supplied from the at least one vessel to the arc chamber for implantation into a substrate, a beam current of boron ions generated from the gas component is 1% to 99%, 1% to 90%, 1% to 80%, 1% to 70%, 1% to 60%, 1% to 50%, 1% to 40%, 1% to 30%, 1% to 20%, 1% to 10%, 1% to 9%, 1% to 8%, 1% to 7%, 1% to 6%, 1% to 5%, 1% to 4%, 1% to 3%, 1% to 2%, 2% to 10%, 3% to 10%, 4% to 10%, 5% to 10%, 6% to 10%, 7% to 10%, 8% to 10%, 9% to 10%, 10% to 99%, 20% to 99%, 30% to 99%, 40% to 99%, 50% to 99%, 60% to 99%, 70% to 99%, 80% to 99%, or 90% to 99% greater than a beam current of boron ions generated from a control gas component.

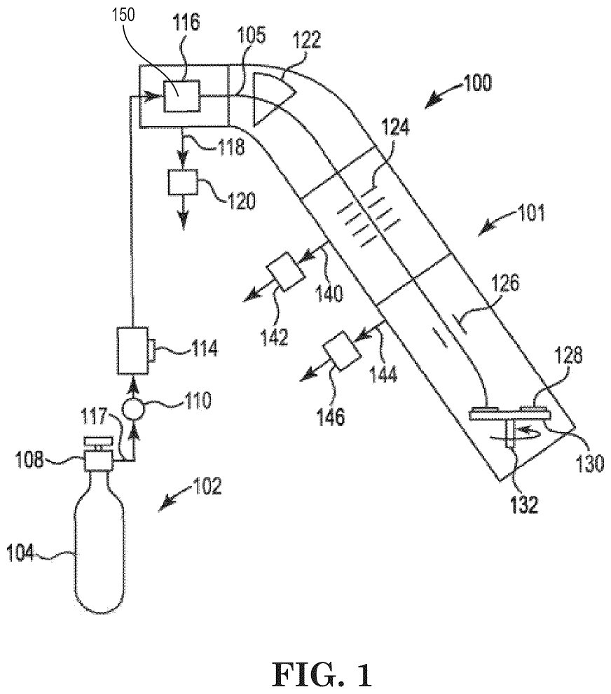

FIG. 1 depicts a schematic representation of an ion implantation system 100, according to some embodiments. As shown in FIG. 1, the ion implantation system 100 includes an arc chamber 150 in fluid communication with at least one vessel 102. In some embodiments, the at least one vessel 102 is included in an assembly, such as, for example and without limitation, a gas supply assembly, which is configured to store and/or supply a gas component to an arc chamber 150. As shown, the ion implantation system 100 also includes an ion implant chamber 101 (e.g., a target chamber).

The assembly comprises the at least one vessel, which may comprise a single vessel or a plurality of vessels. In some embodiments, the at least one vessel comprises the gas component. For example, in some embodiments, the at least one vessel comprises the BF₃. In some embodiments, the at least one vessel comprises the B₂F₄. In some embodiments, the at least one vessel comprises at least one of the second gas components. For example, in some embodiments, the at least one vessel comprises the hydrogen gas. In some embodiments, the at least one vessel comprises the hydride gas. In some embodiments, the at least one vessel comprises the inert gas. In some embodiments, the at least one vessel comprises the ionizable gas. In some embodiments, the at least one vessel comprises the diluent gas. In some embodiments, the at least one vessel comprises the carrier gas. In some embodiments, the at least one vessel comprises the co-gas.

In some embodiments, the at least one vessel comprises a single vessel. In some embodiments, the single vessel comprises the gas component. For example, in some embodiments, the single vessel comprises the BF₃. In some embodiments, the single vessel comprises the B₂F₄. In some embodiments, the single vessel comprises at least one of the second gas components. For example, in some embodiments, the single vessel comprises the hydrogen gas. In some embodiments, the single vessel comprises the hydride gas. In some embodiments, the single vessel comprises the inert gas. In some embodiments, the single vessel comprises the ionizable gas. In some embodiments, the single vessel comprises the diluent gas. In some embodiments, the single vessel comprises the carrier gas. In some embodiments, the single vessel comprises the co-gas. In some embodiments, the single vessel does not comprise at least one of the hydrogen gas, the hydride gas, the inert gas, the ionizable gas, the diluent gas, the carrier gas, the co-gas, or any combination thereof. For example, in some embodiments, at least one additional vessel is provided, wherein the at least one additional vessel comprises at least one of the hydrogen gas, the hydride gas, the inert gas, the ionizable gas, the diluent gas, the carrier gas, the co-gas, or any combination thereof.

In some embodiments, the at least one vessel comprises a plurality of vessels. In some embodiments, the plurality of vessels comprises at least a first vessel and a second vessel, with the BF₃ and the B₂F₄ in different vessels.

In some embodiments, the first vessel comprises the BF₃. In some embodiments, the first vessel comprises at least one of the second gas components. For example, in some embodiments, the first vessel comprises the hydrogen gas. In some embodiments, the first vessel comprises the hydride gas. In some embodiments, the first vessel comprises the inert gas. In some embodiments, the first vessel comprises the ionizable gas. In some embodiments, the first vessel comprises the diluent gas. In some embodiments, the first vessel comprises the carrier gas. In some embodiments, the first vessel comprises the co-gas. In some embodiments, the first vessel does not comprise at least one of the hydrogen gas, the hydride gas, the inert gas, the ionizable gas, the diluent gas, the carrier gas, the co-gas, or any combination thereof.

In some embodiments, the second vessel comprises the B₂F₄. In some embodiments, the second vessel comprises at least one of the second gas components. For example, in some embodiments, the second vessel comprises the hydrogen gas. In some embodiments, the second vessel comprises the hydride gas. In some embodiments, the second vessel comprises the inert gas. In some embodiments, the second vessel comprises the ionizable gas. In some embodiments, the second vessel comprises the diluent gas. In some embodiments, the second vessel comprises the carrier gas. In some embodiments, the second vessel comprises the co-gas. In some embodiments, the second vessel does not comprise at least one of the hydrogen gas, the hydride gas, the inert gas, the ionizable gas, the diluent gas, the carrier gas, the co-gas, or any combination thereof.

In some embodiments, the plurality of vessels further comprises at least one additional vessel. In some embodiments, the at least one addition vessel comprises at least one of the second gas components. For example, in some embodiments, the at least one additional vessel comprises at least one of hydrogen gas, the hydride gas, the inert gas, the ionizable gas, the diluent gas, the carrier gas, the co-gas, or any combination thereof. In some embodiments, the at least one additional vessel comprises the second gas component(s) which are not present in the first vessel and/or the second vessel. In some embodiments, the at least one additional vessel comprises at least one second gas component which is present in the first vessel and/or the second vessel.

When the assembly comprises a plurality of vessels, the assembly may comprise components for regulating the dispensing or discharge of the gases from the plurality of vessels such that the gases are present in the arc chamber 150 at desired concentrations (e.g., volume percentage, partial pressure, etc.). Non-limiting examples of the components include, for example and without limitation, at least one of a regulator, a valve, a control, a processor, a memory, a sensor, a flow controller, or any combination thereof. It will be appreciated that the assembly may comprise additional components without departing from the scope of this disclosure.

While various exemplary embodiments are disclosed above and elsewhere herein, it will be appreciated that any one or more of the foregoing gas components (i.e., the gas component, the second gas component, the BF₃, the B₂F₄, the hydrogen gas, the hydride gas, the inert gas, the ionizable gas, the diluent gas, the carrier gas, the co-gas, or any combination thereof) may be combined or not combined in a single vessel or a plurality of vessels, without departing from the scope of this disclosure. It will further be appreciated that any one or more of the assemblies disclosed herein may be employed in the system 100 without departing from the scope of this disclosure. For simplicity, the various features, embodiments, and/or combinations are not repeated here.

In some embodiments, the at least one vessel 102 is configured to deliver a gas subatmospherically via one or more pressure reduction regulators. In some embodiments, a gas is delivered subatmospherically through the use of an adsorbent.

In some embodiments, a device configured to generate hydrogen via an electrochemical cell is fluidly connected to the ion implantation system 100.

In some embodiments, the arc chamber 150 includes arc chamber walls with interior-plasma facing surfaces. There may be one or more arc chamber liners configured to contact all or a portion of the interior-plasma facing surfaces of the walls of the arc chamber 150.

The at least one vessel 102 may be of a type containing a sorbent medium on which at least one of the gases of the gas component and/or the second gas component is physically adsorbed for storage of the gas, and configured to be desorbed from the sorbent medium, under dispensing conditions, for discharge from the at least one vessel 102. The sorbent medium may be a solid-phase carbon adsorbent material. In some embodiments, the sorbent medium comprises at least one of a porous organic polymer (POP), a zeolite, a zeolitic imidazolate framework (ZIF), a silicalite, a metal-organic framework (MOF), or any combination thereof. Further non-limiting examples of sorbent materials are described in U.S. Patent Application Publication No. 2023/0079446, entitled Composite Adsorbent-Containing Bodies and Related Methods, which is incorporated by reference herein in its entirety. Sorbent-based vessels of such type are commercially available from Entegris. Inc. (Danbury, Conn., USA). Alternatively, the vessel may be of an internally pressure-regulated type, containing one or more pressure regulators in the interior volume of the vessel. Such pressure-regulated vessels are commercially available from Entegris, Inc. (Danbury, Conn., USA). As a still further alternative, the vessel may contain the dopant source material in a solid form that is volatilized, e.g., by heating of the vessel and/or its contents, to generate the gas as a vaporization or sublimation product.

The at least one vessel 102 may include a cylindrical vessel wall 104 enclosing an interior volume holding at least one of the gases of the gas component and/or the second gas component in at least one of an adsorbed state, a free gas state, or a liquefied gas state, or any combination thereof.

The at least one vessel 102 may include a valve head 108 coupled in gas flow communication via a line 117 for dispensing gas. A pressure sensor 110 may be disposed in the line 117, together with a mass flow controller 114; other optional monitoring and sensing components may be coupled with the line, and interfaced with control means such as actuators, feedback and computer control systems, cycle timers, etc.

The ion implant chamber 101 may contain an ion source 116 for receiving the dispensed at least one of the gases of the gas component and/or second gas component from line 117 and for generating an ion beam 105. The ion beam 105 may pass through the mass analyzer unit 122 which selects the ions needed and rejects the non-selected ions.

The selected ions may pass through the acceleration electrode array 124 and then the deflection electrodes 126. The resulting focused ion beam may be impinged on the substrate 128 disposed on the rotatable holder 130 mounted on spindle 132. The ion beam of ions may be used to dope the substrate as desired to form a doped structure.

The respective sections of the ion implant chamber 101 may be exhausted through lines 118, 140 and 144 by means of pumps 120, 142 and 146, respectively.

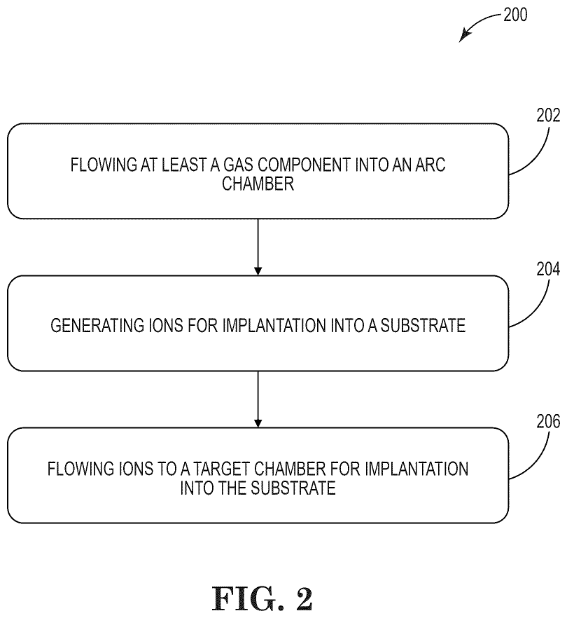

FIG. 2 is a flowchart of a method 200 for ion implantation, according to some embodiments. As shown in FIG. 2, the method 200 for ion implantation may comprise one or more of the following steps: flowing 202 a gas component from at least one vessel into an arc chamber of an ion implantation device; producing 204 boron ions, from at least the gas component, in the arc chamber of the ion implantation device; and flowing 206 the boron ions from the arc chamber to a target chamber for implantation into a substrate. The method 200 for ion implantation may be implemented using any one or more of the assemblies disclosed herein, the ion implantations systems disclosed herein, among others. For simplicity, the assemblies and/or ion implantation systems are not repeated here.

At step 202, the method 200 for ion implantation comprises flowing a gas component from at least one vessel into an arc chamber of an ion implantation device.

In some embodiments, the flowing comprises flowing the gas component and/or the second gas component from a single vessel. In some embodiments, the flowing comprises flowing the gas component and/or the second gas component from a plurality of vessels. In some embodiments, the gas component and/or the second gas component are flowed from different vessels. In some embodiments, at least one of the gas components and at least one of the second gas components are flowed from the same vessel. In some embodiments, at least one of the gas components and at least one of the second gas components are flowed from different vessels. In some embodiments, the gas component is flowed from the same vessel. In some embodiments, the gas component is flowed from different vessels. In some embodiments, the second gas component is flowed from the same vessel. In some embodiments, the second gas component is flowed from different vessels. In some embodiments, the flowing comprises dispensing gas from the at least one vessel. In some embodiments, the flowing comprises discharging a gas from the at least one vessel. In some embodiments, the flowing comprises supplying a gas from the at least one vessel. In some embodiments, the flowing comprises actuating a valve so as to flow gas from the at least one vessel. In some embodiments, the flowing comprises pumping a gas from the at least one vessel. In some embodiments, the flowing comprises flowing the BF₃ from a first vessel into the arch chamber of the ion implantation device; and flowing the B₂F₄ from a second vessel into the arc chamber of the ion implantation device. In some embodiments, the flowing comprises flowing at least one of a hydrogen gas, a hydride gas, an inert gas, or any combination thereof, into the arc chamber of the ion implantation device.

In some embodiments, the flowing is conducted at a flow rate of 0.1 sccm to 10 sccm, or any range or subrange between 0.1 sccm and 10 sccm. In some embodiments, the flowing is conducted at a flow rate of 0.1 sccm to 9.5 sccm, 0.1 sccm to 9 sccm, 0.1 sccm to 8.5 sccm, 0.1 sccm to 8 sccm, 0.1 sccm to 7.5 sccm, 0.1 sccm to 7 sccm, 0.1 sccm to 6.5 sccm, 0.1 sccm to 6 sccm, 0.1 sccm to 5.5 sccm, 0.1 sccm to 5 sccm, 0.1 sccm to 4.5 sccm, 0.1 sccm to 4 sccm, 0.1 sccm to 3.5 sccm, 0.1 sccm to 3 sccm, 0.1 sccm to 2.5 sccm, 0.1 sccm to 2 sccm, 0.1 sccm to 1.5 sccm, 0.1 sccm to 1 sccm, 0.1 sccm to 0.5 sccm, 0.5 sccm to 10 sccm, 1 sccm to 10 sccm, 1.5 sccm to 10 sccm, 2 sccm to 10 sccm, 2.5 sccm to 10 sccm, 3 sccm to 10 sccm, 3.5 sccm to 10 sccm, 4 sccm to 10 sccm, 4.5 sccm to 10 sccm, 5 sccm to 10 sccm, 5.5 sccm to 10 sccm, 6 sccm to 10 sccm, 6.5 sccm to 10 sccm, 7 sccm to 10 sccm, 7.5 sccm to 10 sccm, 8 sccm to 10 sccm, 8.5 sccm to 10 sccm, 9 sccm to 10 sccm, or 9.5 sccm to 10 sccm.

At step 204, the method 200 for ion implantation comprises generating ions, from at least the gas component, in the arc chamber (e.g., an ion source) of the ion implantation device.

In some embodiments, the generating comprises producing ions, from at least the gas component, in the arc chamber of the ion implantation device. In some embodiments, the generating comprises ionizing at least one of the gas component, the second gas component, or any combination thereof. In some embodiments, the generating comprises In some embodiments, the generating comprises exposing at least one of the gas component, the second gas component, or any combination thereof to electromagnetic radiation. In some embodiments, the electromagnetic radiation comprises at least one of radio frequency radiation, microwave radiation, or any combination thereof. In some embodiments, the generating comprises colliding the gas component, the second gas component, or any combination thereof, with particles. In some embodiments, the generating comprises bombarding at least one of the gas component, the second gas component, or any combination thereof, with particles.

At step 206, the method 200 for ion implantation comprises flowing the ions from the arc chamber to a target chamber for implantation into a substrate.

In some embodiments, the flowing comprises flowing the ions in a beam from the arc chamber to a target chamber for implantation into a substrate. In some embodiments, the flowing comprises accelerating the ions to an energy sufficient for implantation into a substrate. In some embodiments, the flowing comprises extracting boron ions or boron-containing ions from ions for impingement upon a substrate. In some embodiments, the flowing comprises selecting boron ions and/or boron-containing ions from ions for implantation into a substrate. In some embodiments, the flowing comprises flowing the ions through an electric field. In some embodiments, the flowing comprises flowing the ions through a mass analyzer. In some embodiments, the flowing comprises beaming the ions to a target chamber for implantation into a substrate.

It will be appreciated that any one or more of the embodiments disclosed herein may be employed in alone or in combination, without departing from the scope of this disclosure.

### Example 1

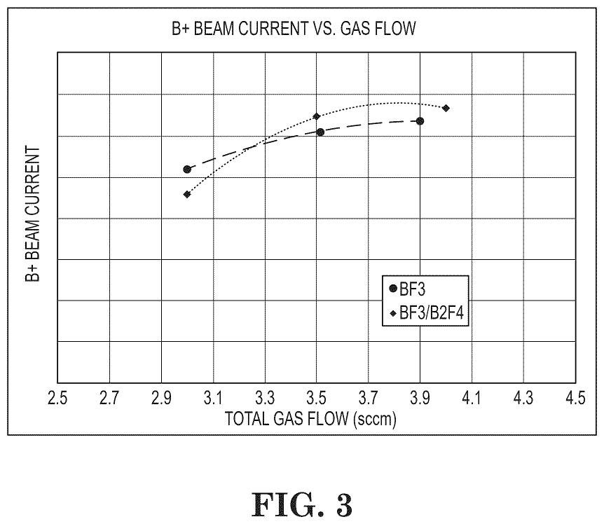

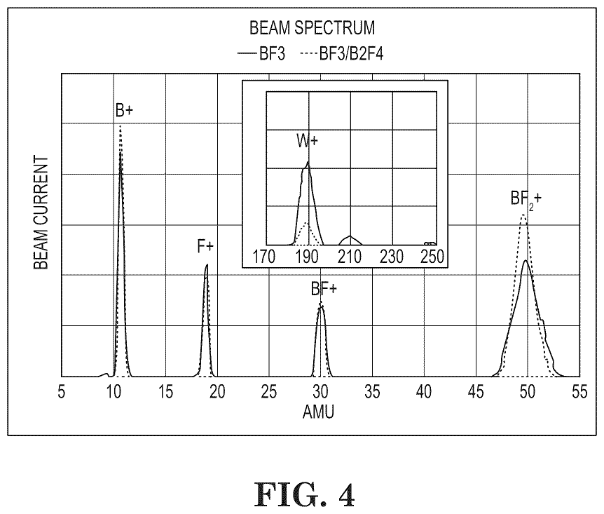

The B⁺ beam current was measured for a BF₃/B₂F₄ gas mixture (Sample A) at varying gas flow rates and compared to a control (Control A). Control A comprised BF₃ gas, without B₂F₄. Sample A comprised a gas mixture of 15% by volume of B₂F₄, with a remainder of the gas mixture comprised of BF₃. Unless otherwise provided herein, the percent by volume is based on a total volume of the gas mixture. The conditions for measurement were the same for Sample A and Control A, and are referred to herein as Conditions 1. FIG. 3 is a graphical view of B⁺ beam current for varying total gas flow (sccm) for Control A and Sample A. FIG. 4 is a graphical view of a beam spectrum for Control A and Sample A. As shown in FIG. 3, the B⁺ beam current for Sample A was markedly greater than the B⁺ beam current for Control A, as the total gas flow increased from 3.1 sccm to 3.3 sccm. Furthermore, the mixture of BF₃ and B₂F₄ in Sample A exhibited markedly reduced W⁺ peaks (inset, dashed lines), as shown in FIG. 4.

### Example 2

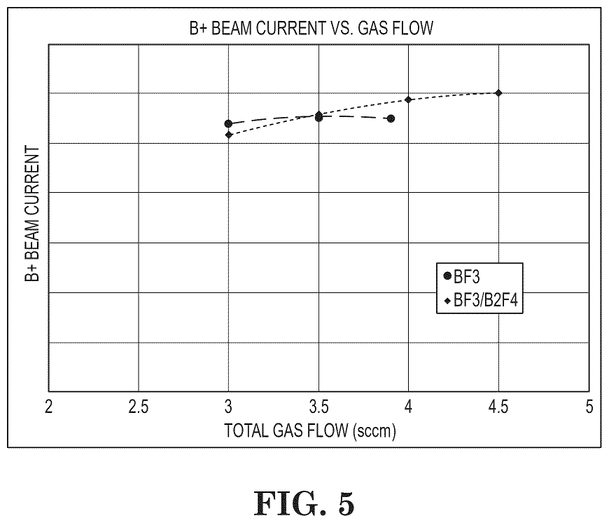

The B⁺ beam current was measured for a BF₃/B₂F₄ gas mixture (Sample B) at varying gas flow rates and compared to a control (Control B). Control B comprised BF₃ gas, without B₂F₄. Sample B comprised a gas mixture of 15% by volume of B₂F₄, with a remainder of the gas mixture comprised of BF₃. The conditions for measurement were the same for Sample B and Control B, and are referred to herein as Conditions 2. FIG. 5 is a graphical view of B⁺ beam current for varying total gas flow (sccm) for Control B and Sample B. As shown in FIG. 5, the B⁺ beam current for Sample B was markedly greater than the B⁺ beam current for Control B, as the total gas flow increased above 3.5 sccm.

### Example 3

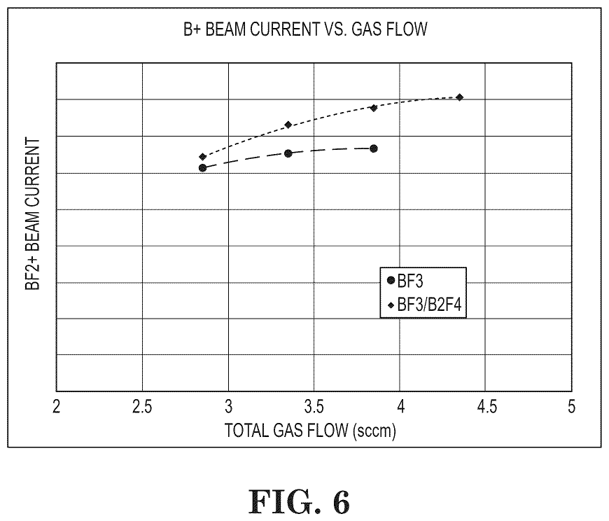

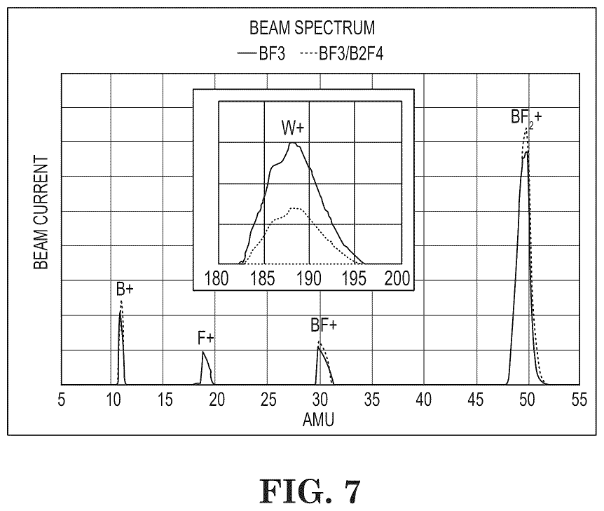

The BF₂⁺ beam current was measured for Sample C at varying gas flow rates and compared to Control C. The conditions for measurement were the same as Example 1. FIG. 6 is a graphical view of BF₂⁺ beam current for varying total gas flow (sccm) for Control C and Sample C. FIG. 7 is a graphical view of a beam spectrum for Control C and Sample C. As shown in FIG. 6, the BF₂⁺ beam current for Sample C was markedly greater than the BF₂⁺ beam current for Control C, for all total gas flows. Furthermore, the mixture of BF₃ and B₂F₄ in Sample C exhibited markedly reduced W⁺ peaks (inset, dashed lines), as shown in FIG. 7.

### Example 4

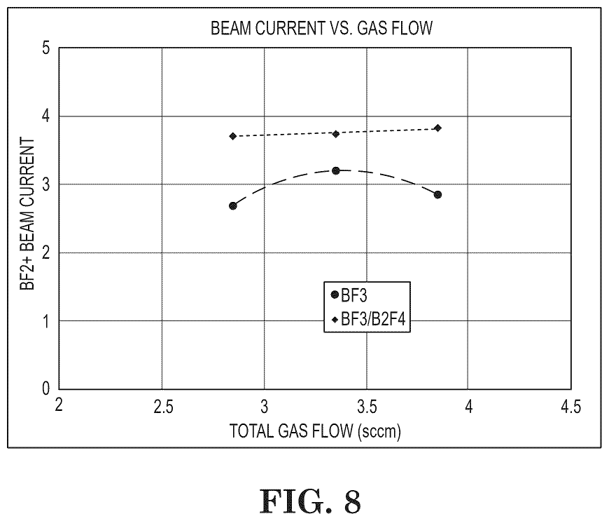

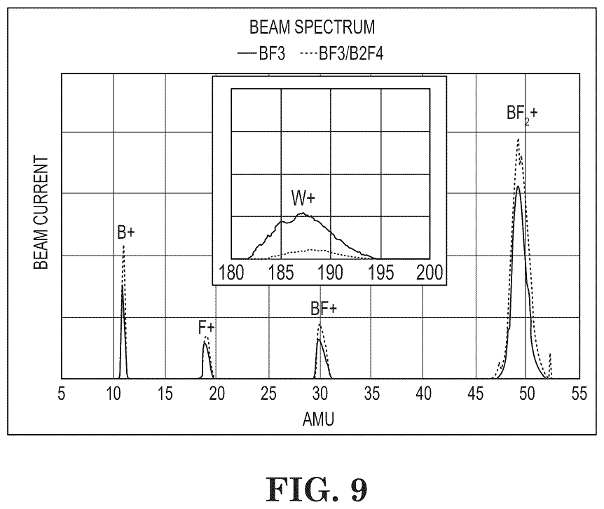

The BF₂⁺ beam current was measured for Sample D at varying gas flow rates and compared to Control D. The conditions for measurement were the same as Example 2. FIG. 8 is a graphical view of BF₂⁺ beam current for varying total gas flow (sccm) for Control D and Sample D. FIG. 9 is a graphical view of a beam spectrum for Control D and Sample D. As shown in FIG. 8, the BF₂⁺ beam current for Sample D was markedly greater than the BF₂⁺ beam current for Control D, for all total gas flows. Furthermore, the mixture of BF₃ and B₂F₄ in Sample D exhibited markedly reduced W⁺ peaks (inset, dashed lines), as shown in FIG. 9.

### Example 5

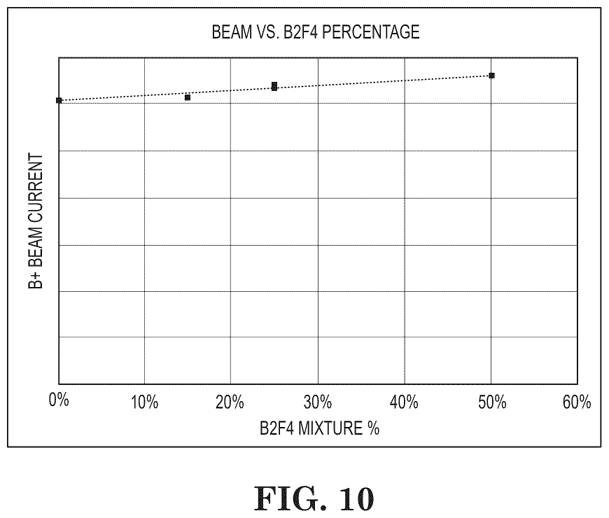

FIG. 10 is a graphical view of B⁺ beam current for gas mixtures with varying B₂F₄ concentrations, according to some embodiments. At 0% by volume of B₂F₄, the gas mixture comprised 100% BF₃. As shown in FIG. 10, the B⁺ beam current unexpectedly increased with the addition of B₂F₄ to the gas mixture across all tested concentration ranges, which included 0% by volume to 50% by volume of B₂F₄.

### Aspects

Various Aspects are described below. It is to be understood that any one or more of the features recited in the following Aspect(s) can be combined with any one or more other Aspect(s).

Aspect 1. An assembly comprising:

at least one vessel configured to be fluidly coupled to an arc chamber of an ion implantation device,
wherein the at least one vessel comprises a gas component,
   wherein the gas component comprises BF₃ and B₂F₄; wherein, when the gas component is supplied from the at least one vessel to the arc chamber for implantation into a substrate, a beam current of boron ions generated from the gas component is greater than a beam current of boron ions generated from a control gas component.

Aspect 2. The assembly according to Aspect 1, wherein the at least one vessel comprises:

a first vessel comprising the BF₃; and

a second vessel comprising the B₂F₄.

Aspect 3. The assembly according to any one or more of Aspects 1-2, wherein the at least one vessel is a single vessel comprising the BF₃ and the B₂F₄.

Aspect 4. The assembly according to Aspect 3, wherein the single vessel comprises:

1% to 80% by volume of the B₂F₄ based on a total volume of the gas component.

Aspect 5. The assembly according to Aspect 3, wherein the single vessel comprises:

2% to 50% by volume of the B₂F₄ based on a total volume of the gas component.

Aspect 6. The assembly according to Aspect 3, wherein the single vessel comprises:

5% to 20% by volume of the B₂F₄ based on a total volume of the gas component.

Aspect 7. The assembly according to any one or more of Aspects 1-6, wherein the at least one vessel further comprises at least one of a hydrogen gas, a hydride gas, an inert gas, or any combination thereof.

Aspect 8. The assembly according to Aspect 7, wherein the hydride gas comprises a compound of the formula:

AₓH_{y},

where:
A is an element other than hydrogen;
x is 1 to 8; and
y is 1 to 8.

Aspect 9. The assembly according to Aspect 7, wherein the hydride gas comprises at least one of PH₃, AsH₃, B₂H₆, SiH₄, GeH₄, NH₃, or any combination thereof.

Aspect 10. The assembly according to Aspect 7, wherein the inert gas comprises at least one of a nitrogen gas, a hydrogen gas, a neon gas, an argon gas, a krypton gas, a xenon gas, or any combination thereof.

Aspect 11. The assembly according to any one or more of Aspects 1-10, wherein at least one of the BF₃, the B₂F₄, or any combination thereof, comprises an isotopically enriched boron.

Aspect 12. A system for ion implantation, comprising:

an assembly fluidly comprising at least one vessel that is fluidly coupled to an arc chamber of an ion implantation device;
wherein the at least one vessel comprises a gas component;
   wherein the gas component comprises BF₃ and B₂F₄;
   wherein, when the gas component is supplied from the at least one vessel to the arc chamber for implantation into a substrate, a beam current of boron ions generated from the gas component is greater than a beam current of boron ions generated from a control gas component.

Aspect 13. The system according to Aspect 12, wherein the at least one vessel comprises:

a first vessel comprising the BF₃; and

a second vessel comprising the B₂F₄.

Aspect 14. The system according to any one or more of Aspects 12-13, wherein the at least one vessel is a single vessel comprising the BF₃ and the B₂F₄.

Aspect 15. The system according to any one or more of Aspects 12-14, wherein the at least one vessel further comprises at least one of a hydrogen gas, a hydride gas, an inert gas, or any combination thereof.

Aspect 16. The system according to any one or more of Aspects 12-15, wherein at least one of the BF₃, the B₂F₄, or any combination thereof, comprises an isotopically enriched boron.

Aspect 17. A method comprising:

flowing at least a gas component from at least one vessel into an arc chamber of an ion implantation device,
wherein the gas component comprises BF₃ and B₂F₄;

generating ions, from at least the gas component, in the arc chamber of the ion implantation device; and

flowing the ions in a beam from the arc chamber to a target chamber for implantation into a substrate.

Aspect 18. The method according to Aspect 17, wherein flowing the gas component comprises flowing the gas component from a single vessel comprising the gas component.

Aspect 19. The method according to any one or more of Aspects 17-18, wherein flowing the gas component comprises:

flowing the BF₃ from a first vessel into an arch chamber of the ion implantation device; and

flowing the B₂F₄ from a second vessel into the arc chamber of the ion implantation device.

Aspect 20. The method according to Aspect 19, further comprising:

flowing at least one of a hydrogen gas, a hydride gas, an inert gas, or any combination thereof, into the arc chamber of the ion implantation device.

It is to be understood that changes may be made in detail, especially in matters of the construction materials employed and the shape, size, and arrangement of parts without departing from the scope of the present disclosure. This Specification and the embodiments described are examples, with the true scope and spirit of the disclosure being indicated by the claims that follow.

What is claimed is:

1. An assembly comprising:
at least one vessel configured to be fluidly coupled to an arc chamber of an ion implantation device,
wherein the at least one vessel comprises a gas component,
wherein the gas component comprises BF₃ and B₂F₄;
wherein, when the gas component is supplied from the at least one vessel to the arc chamber for implantation into a substrate, a beam current of boron ions generated from the gas component is greater than a beam current of boron ions generated from a control gas component.

2. The assembly of claim 1, wherein the at least one vessel comprises:
a first vessel comprising the BF₃; and
a second vessel comprising the B₂F₄.

3. The assembly of claim 1, wherein the at least one vessel is a single vessel comprising the BF₃ and the B₂F₄.

4. The assembly of claim 3, wherein the single vessel comprises:
1% to 80% by volume of the B₂F₄ based on a total volume of the gas component.

5. The assembly of claim 3, wherein the single vessel comprises:
2% to 50% by volume of the B₂F₄ based on a total volume of the gas component.

6. The assembly of claim 3, wherein the single vessel comprises:
5% to 20% by volume of the B₂F₄ based on a total volume of the gas component.

7. The assembly of claim 1, wherein the at least one vessel further comprises at least one of a hydrogen gas, a hydride gas, an inert gas, or any combination thereof.

8. The assembly of claim 7, wherein the hydride gas comprises a compound of the formula:
AₓH_{y},
where:
A is an element other than hydrogen;
x is 1 to 8; and
y is 1 to 8.

9. The assembly of claim 7, wherein the hydride gas comprises at least one of PH₃, AsH₃, B₂H₆, SiH₄, GeH₄, NH₃, or any combination thereof.

10. The assembly of claim 7, wherein the inert gas comprises at least one of a nitrogen gas, a hydrogen gas, a neon gas, an argon gas, a krypton gas, a xenon gas, or any combination thereof.

11. The assembly of claim 1, wherein at least one of the BF₃, the B₂F₄, or any combination thereof, comprises an isotopically enriched boron.

12. A system for ion implantation, comprising:
an assembly fluidly comprising at least one vessel that is fluidly coupled to an arc chamber of an ion implantation device;
wherein the at least one vessel comprises a gas component;
wherein the gas component comprises BF₃ and B₂F₄;
wherein, when the gas component is supplied from the at least one vessel to the arc chamber for implantation into a substrate, a beam current of boron ions generated from the gas component is greater than a beam current of boron ions generated from a control gas component.

13. The system of claim 12, wherein the at least one vessel comprises:
a first vessel comprising the BF₃; and
a second vessel comprising the B₂F₄.

14. The system of claim 12, wherein the at least one vessel is a single vessel comprising the BF₃ and the B₂F₄.

15. The system of claim 12, wherein the at least one vessel further comprises at least one of a hydrogen gas, a hydride gas, an inert gas, or any combination thereof.

16. The system of claim 12, wherein at least one of the BF₃, the B₂F₄, or any combination thereof, comprises an isotopically enriched boron.

17. A method comprising:
flowing at least a gas component from at least one vessel into an arc chamber of an ion implantation device,
wherein the gas component comprises BF₃ and B₂F₄;
generating ions, from at least the gas component, in the arc chamber of the ion implantation device; and
flowing the ions in a beam from the arc chamber to a target chamber for implantation into a substrate.

18. The method of claim 17, wherein flowing the gas component comprises flowing the gas component from a single vessel comprising the gas component.

19. The method of claim 17, wherein flowing the gas component comprises:
flowing the BF₃ from a first vessel into an arch chamber of the ion implantation device; and
flowing the B₂F₄ from a second vessel into the arc chamber of the ion implantation device.

20. The method of claim 19, further comprising:
flowing at least one of a hydrogen gas, a hydride gas, an inert gas, or any combination thereof, into the arc chamber of the ion implantation device.
